(19) United States
(12) Patent Application Publication
(10) Pub. No.: US 2007/0045615 A1
(43) Pub. Date: Mar. 1, 2007

(54) NON-VOLATILE ORGANIC RESISTANCE RANDOM ACCESS MEMORY DEVICE AND METHOD OF MANUFACTURING THE SAME

(75) Inventors: Byeong-Ok CHO, Seoul (KR); Moon-Sook LEE, Seoul (KR); Takahiro YASUE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-Do, (KR)

(21) Appl. No.: 11/465,040

(22) Filed: Aug. 16, 2006

(30) Foreign Application Priority Data
Aug. 31, 2005 (KR) 2005-80662

(51) Int. Cl. H01L 29/08

(52) U.S. Cl. 257/40

(57) ABSTRACT

A non-volatile organic resistance memory device including a first electrode, a second electrode, and a polyimide layer interposed between the first and second electrodes. The polyimide layer has a thickness such that a resistance of the polyimide layer varies in accordance with a potential difference between the first and second electrodes.

### CROSS-REFERENCE TO RELATED APPLICATION

This application claims priority tinder 35 USC §119 to Korean Patent Application No. 2005-80662, filed on Aug. 31, 2005, the contents of which are herein incorporated by reference in their entirety for all purposes.

### BACKGROUND

1. Field of the Invention

This disclosure relates to a non-volatile organic resistance random access memory device and a method of manufacturing the same. More particularly, the present invention relates to a non-volatile organic resistance random access memory device that is capable of storing data in accordance with states of a resistance between electrodes, and a method of manufacturing the non-volatile organic resistance random access memory device.

2. Description of the Related Art

Recently, various non-volatile memory device structures have been studied for use in the new generation of memory devices, substituting for a dynamic random access memory (DRAM). Research on the non-volatile memory devices has been aimed at enlarging capacity, increasing speed and lowering consumption power.

Examples of the next generation of the non-volatile memory devices include a magnetic random access memory (MRAM), a ferroelectric random access memory (FRAM), a phase-changeable random access memory (PRAM), and the like. In addition, a resistance random access memory (RRAM), using a phenomenon that a resistance is changed in accordance with a specific voltage pulse, has been actively studied.

The RRAM has a structure that includes two electrodes and a variable resistor interposed between the electrodes. When a voltage is applied to the electrodes, a resistance of the variable resistor is increased or decreased.

Conventional variable resistor structures include a variable resistor that includes organic polymer and/or inorganic oxide containing a sufficient amount of electron donors and electron acceptors, and a variable resistor that has a sandwich structure including low-polymer organic and metal nano-particles or clusters.

However, the organic materials used for the variable resistor have thermal, mechanical and chemical stabilities inferior to those of the inorganic material. For example, when the devices using an organic such as an organic light emitting display (OLED), an organic thin film transistor (OTFT), and the like are exposed to heat above about 100° C., or to moistures and oxygen, capacities of the devices may rapidly deteriorate.

Thus, it is difficult to manufacture an RRAM with organic materials using conventional semiconductor manufacturing processes. For example, high temperature processes such as an exposing process, a developing process and a baking process used in a photolithography process, and a dry etching process may cause damage to the RRAM. In addition, processes using chemicals such as a wet etching process, a cleaning process and a stripping process also may not be employed for forming an RRAM.

Further, it is difficult to uniformly input and mix the nano-particles and the clusters in the organic material. In particular, the implanting process to input and mix the nano-particles and the clusters may cause problems related to contaminants.

Furthermore, if the nano-particles include a metal or a ceramic, and remain in the material for a long time, the nano-particles may become agglomerated to one another so that the agglomerated nano-particles become very unstable by being segregated from the organic material. As a result, the organic material with the nano-particles may be unstable.

When the electron donor and electron acceptor include a low-polymer organic material, the low-polymer organic material thermally decomposes at a temperature of about 100° C. Thus, characteristics of the variable resistor are deteriorated in subsequent processing. Furthermore, the characteristics of the variable resistor are deteriorated during operating the RRAM. As a result, the conventional RRAM has poor reliability.

Therefore, there remains a need for an RRAM including a variable resistor, which has good thermal, chemical and mechanical stabilities for allowing the use of general semiconductor manufacturing processes and reproducibly exhibits a characteristic changed to a high resistance or a low resistance.

### SUMMARY

An embodiment includes non-volatile organic resistance memory device including a first electrode, a second electrode, and a polyimide layer interposed between the first and second electrodes. The polyimide layer has a thickness such that a resistance of the polyimide layer varies in accordance with a potential difference between the first and second electrodes,

Another embodiment includes a method of manufacturing a non-volatile organic resistance memory device including forming a first electrode on a substrate, forming a polyimide layer on the first electrode, and forming a second electrode on the polyimide layer. The polyimide layer is formed having a thickness such that a resistance of the polyimide layer varies in accordance with a potential difference between the first and second electrodes.

### BRIEF DESCRIPTION OF THE DRAWINGS

The above and other features and advantages will become readily apparent by reference to the following detailed description when considered in conjunction with the accompanying drawings wherein:

FIG. 1 is a cross-sectional view illustrating a non-volatile organic resistance random access memory device in accordance with an embodiment;

FIG. 2 is a view illustrating a structure of high-polymer polyimide;

FIG. 3 is a cross-sectional view illustrating a non-volatile organic resistance random access memory device in accordance with another embodiment;

FIG. 4 is a perspective view illustrating unit cells of the non-volatile organic resistance random access memory device in FIG. 3;

FIG. 5 is a circuit diagram illustrating an array of the non-volatile organic resistance random access memory device in FIG. 3;

FIGS. 6 to 8 are cross-sectional views illustrating a method of manufacturing the non-volatile organic resistance random access memory device in FIG. 3;

FIG. 9 is a cross-sectional view illustrating a non-volatile organic resistance random access memory device in accordance with yet another embodiment;

FIGS. 10 to 14 are cross-sectional views illustrating a method of manufacturing the non-volatile organic resistance random access memory device in FIG. 9;

FIG. 15 is a graph illustrating switching characteristics of an embodiment of the non-volatile organic resistance random access memory device;

FIG. 16 is a graph illustrating setting characteristics of a first sample corresponding to the non-volatile organic resistance random access memory device in accordance with an embodiment;

FIG. 17 is a graph illustrating resetting characteristics of the first sample;

FIG. 18 is a graph illustrating setting characteristics of a second sample corresponding to the non-volatile organic resistance random access memory device in accordance with an embodiment;

FIG. 19 is a graph illustrating resetting characteristics of the second sample; and

FIG. 20 is a graph illustrating resistance variances of the first sample that is repeatedly set and reset.

### DETAILED DESCRIPTION

Embodiments are described more fully hereinafter with reference to the accompanying drawings. Embodiments may take many different forms and should not be construed as limited to the embodiments set forth herein. Rather, these embodiments are provided so that this disclosure will be thorough and complete, and will fully convey the scope of the following claims to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items. It will be understood that, although the terms first, second, and the like may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. In addition, the device may be otherwise oriented (for example, rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a cross-sectional view illustrating a non-volatile organic resistance random access memory device in accordance with an embodiment.

Referring to FIG. 1, a non-volatile organic resistance random access memory (RAM) device includes a first electrode 10, a second electrode 14 and a polyimide layer 12.

The first electrode 10 may be formed on a semiconductor substrate (not shown) such as a silicon substrate, a silicon-on-insulation (SOI) substrate, and the like. Alternatively, the first electrode 10 may be formed on a flexible substrate (not shown) including inorganic material such as a glass or a stable organic material. The first electrode 10 functions as a lower electrode of the non-volatile organic resistance RAM device.

Examples of the first electrode 10 include a metal layer, a metal nitride layer, a doped semiconductor layer and the like. These can be used alone or in any combination. In this example embodiment, the metal layer or the metal nitride layer is used for the first electrode 10.

Specific examples of the first electrode 10 include an aluminum (Al) layer, a copper (Cu) layer, a titanium nitride (TiN) layer, a titanium aluminum nitride (TixAlyNz) layer, an iridium (Ir) layer, a platinum (Pt) layer, a silver (Ag) layer, a gold (Au) layer, a polysilicon layer, a tungsten (W) layer, a titanium (Ti) layer, a tantalum (Ta) layer, a tantalum nitride (TaN) layer, a tungsten nitride (WN) layer, a nickel (Ni) layer, a cobalt (Co) layer, a chromium (Cr) layer, an antimony (Sb) layer, an iron (Fe) layer, a molybdenum (Mo) layer, a palladium (Pd) layer, a tin (Sn) layer, a zirconium (Zr) layer, a zinc (Zn) layer, and the like. These can be used alone or in a combination thereof.

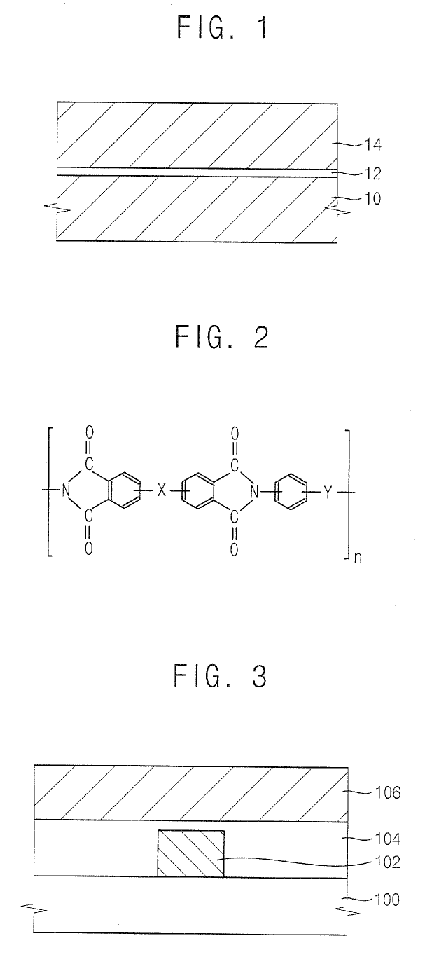

The polyimide layer 12 as a variable resistor is formed on the first electrode 10. The polyimide layer 12 is known generically as a heat-resistant resin that has imide bonds in the main chain. Functional groups may be variously added to the polyimide layer 12. FIG. 2 is a view illustrating a structure of high-polymer polyimide. In FIG. 2, X and Y represent bondable functional groups.

Further, to readily form the second electrode 14 on the polyimide layer 12, the polyimide layer 12 may have a flat upper face.

In this embodiment, the polyimide layer 12 has a thickness for allowing conductive types of the polyimide layer 12 to vary in accordance with a potential difference between the first and second electrodes 10 and 14. Thus, the polyimide layer 12 may have a high resistance or a low resistance. In particular, when the polyimide layer 12 interposed between the first and second electrodes 10 and 14 has a thickness below about 10 Å, charges tunnel into the polyimide layer 12 so that the polyimide layer 12 may not function as the variable resistor. In contrast, when the polyimide layer 12 interposed between the first and second electrodes 10 and 14 has a thickness of above about 500 Å, the first and second electrodes 10 and 14 are electrically isolated from each other so that the polyimide layer 12 may not function as the variable resistor. Thus, the polyimide layer 12 may have a thickness of about 10 Å to about 500 Å, preferably about 10 Å to about 300 Å.

The polyimide layer 12 may be formed by coating a polyimide precursor on the first electrode 10 and then by an imide reaction of the polyimide precursor. When the polyimide layer 12 is formed by the coating of the polyimide precursor, the polyimide layer 12 may have the flat upper face without performing an additional planarizing process. Alternatively, the polyimide layer 12 may be formed by a chemical vapor deposition (CVD) process.

When the polyimide layer 12 has the thickness of about 10 Å to about 500 Å, the polyimide layer 12 functions sufficiently as the variable resistor without mixing impurities with the polyimide layer 12. This may result from nano-particles that are self-generated at an interface between the first electrode 10 and the polyimide layer 12 by a reaction between the first electrode 10 and the polyimide layer 12 during forming the polyimide layer. That is, while the polyimide layer 12 is formed, the nano-particles are generated at the interface between the first electrode 10 and the polyimide layer 12. Here, positions of the interface where the nano-particles are generated vary in accordance with kinds of the first electrode 10. The nano-particles store charges in the polyimide layer 12 or discharge the charges from the polyimide layer 12 in accordance with the potential difference between the first and second electrodes 10 and 14 to change the conductivity of the polyimide layer 12, thereby causing the polyimide layer 12 to act as the variable resistor.

As described above, when the polyimide layer 12 is used as the variable resistor, complicated processes such as an additional process for injecting the nano-particles into the polyimide layer 12 may not be required, because the nano-particles are self-generated in the polyimide layer 12.

Furthermore, the polyimide layer 12 has a high glass transition temperature Tg, strong mechanical strength and improved chemical stability. Thus, when the polyimide layer 12 is used as the variable resistor of the non-volatile organic resistance RAM device, the non-volatile organic resistance RAM device may have improved durability and reliability.

The second electrode 14 is formed on the flat upper face of the polyimide layer 12. Examples of the second electrode 14 include a metal layer, a metal nitride layer, a doped semiconductor layer and the like. These can be used alone or in a combination thereof. In this example embodiment, the metal layer or the metal nitride layer is used for the second electrode 14.

Particularly, examples of the second electrode 14 include an aluminum (Al) layer, a copper (Cu) layer, a titanium nitride (TiN) layer, a titanium aluminum nitride (TixAlyNz) layer, an iridium (Ir) layer, a platinum (Pt) layer, a silver (Ag) layer, a gold (Au) layer, a polysilicon layer, a tungsten (W) layer, a titanium (Ti) layer, a tantalum (Ta) layer, a tantalum nitride (TaN) layer, a tungsten nitride (WN) layer, a nickel (Ni) layer, a cobalt (Co) layer, a chromium (Cr) layer, an antimony (Sb) layer, an iron (Fe) layer, a molybdenum (Mo) layer, a palladium (Pd) layer, a tin (Sn) layer, a zirconium (Zr) layer, a zinc (Zn) layer, and the like. These can be used alone or in a combination thereof.

According to this embodiment, the non-volatile organic resistance RAM device has a structure that includes the first electrode 10, the second electrode 14 and the polyimide layer 14 interposed between the first and second electrodes 10 and 14. Further, the polyimide layer 12 may have the improved chemical stability and durability. Particularly, the polyimide layer 12 does not decompose at a temperature of about 500° C. so that the polyimide layer may have improved reliability. Therefore, the non-volatile organic resistance RAM device may have improved reliability.

Furthermore, since the polyimide layer 12 continuously possesses the high resistance or the low resistance set by the potential difference between the first and second electrodes 10 and 14, the polyimide layer 12 may be used in the non-volatile organic resistance random access memory device providing stable operation. Furthermore, the resistance characteristics of the polyimide layer 12 are reproducible. As a result, the non-volatile organic resistance RAM device may have good operational characteristics.

Hereinafter, a method of manufacturing the non-volatile organic resistance RAM device in FIG. 1 is illustrated.

The substrate on which the non-volatile organic resistance RAM device is formed is prepared. Examples of the substrate include the semiconductor substrate such as a silicon substrate, a silicon-on-insulation (SOI) substrate or a flexible substrate including an inorganic material Such as a glass or a stable organic material.

The first electrode 10 is formed on the substrate. Examples of the first electrode 10 include a metal layer, a metal nitride layer, a doped semiconductor layer, and the like. These can be used alone or in a combination thereof.

In this example embodiment, the metal layer or the metal nitride layer is used for the first electrode 10. Particularly, examples of the first electrode 10 include an aluminum (Al) layer, a copper (Cu) layer, a titanium nitride (TiN) layer, a titanium aluminum nitride (TixAlyNz) layer, an iridium (Ir) layer, a platinum (Pt) layer, a silver (Ag) layer, a gold (Au) layer, a polysilicon layer, a tungsten (W) layer, a titanium (Ti) layer, a tantalum (Ta) layer, a tantalum nitride (TaN) layer, a tungsten nitride (W-N) layer, a nickel (Ni) layer, a cobalt (Co) layer, a chromium (Cr) layer, an antimony (Sb) layer, an iron (Fe) layer, a molybdenum (Mo) layer, a palladium (Pd) layer, a tin (Sn) layer, a zirconium (Zr) layer, a zinc (Zn) layer, and the like. These can be used alone or in a combination thereof.

The First electrode 10 may be formed by a physical vapor deposition (PVD) process or a CVD process. When the first electrode 10 includes the copper layer, the copper layer may be formed by an electroplating process or an electroless plating process.

The polyimide layer 12 having a thickness of about 10 Å to about 500 Å is formed on the first electrode 10. Particularly, the polyimide precursor may be spin-coated on the first electrode 10. Here, an example the polyimide precursor includes polyamic acid that is formed by the reaction of diamine and anhydride in a solvent. The polyimide precursor is thermally treated to convert the polyimide precursor into the polyimide layer 12. That is, the polyamic acid is imidified by the thermal treatment to form the polyimide layer 12.

Here, when the thermal treatment is carried out at a temperature below about 150° C. the imide reaction does not normally occur. On the contrary, when the thermal treatment is carried out at a temperature above about 450° C., the polyimide layer 12 and the first electrode 10 are deteriorated. Thus, the thermal treatment is carried out at a temperature of about 150° C. to about 450° C., preferably about 200° C. to about 450° C. Furthermore, the thermal treatment may be performed under a nitrogen atmosphere.

When the first electrode 10 includes the metal layer or the metal nitride layer, the polyamic acid penetrates into the first electrode 10. The polyamic acid reacts with the first electrode 10 to form carboxylate. The carboxylate is decomposed into the nano-particles. The nano-particles are positioned at the interface between the polyimide layer 12 and the first electrode 10.

Here, distribution characteristics and density characteristics of the nano-particles may vary depending on the types and thicknesses of the first electrode 10, and a thermal treatment temperature with respect to the polyamic acid. Thus, the types and the thicknesses of the first electrode 10, and the thermal treatment temperature with respect to the polyamic acid may be adjusted by changing the distribution characteristics and the density characteristics of the nano-particles to alter characteristics of the polyimide layer 12 that forms the variable resistor. The characteristics of the variable resistor include a threshold voltage for setting the variable resistor to the low resistance, and for changing the variable resistance to the high resistance.

Alternatively, the polyimide layer 12 may be formed by a chemical vapor deposition (CVD) process.

The second electrode 14 is formed on the polyimide layer 12. Examples of the second electrode 14 include a metal layer, a metal nitride layer, a doped semiconductor layer, and the like. These can be used alone or in a combination thereof. In this example embodiment, the metal layer or the metal nitride layer is used for the second electrode 14.

Particularly, examples of the second electrode 14 include an aluminum (Al) layer, a copper (Cu) layer, a titanium nitride (TiN) layer, a titanium aluminum nitride (TixAlyNz) layer, an iridium (Ir) layer, a platinum (Pt) layer, a silver (Ag) layer, a gold (Au) layer, a polysilicon layer, a tungsten (W) layer, a titanium (Ti) layer, a tantalum (Ta) layer, a tantalum nitride (TaN) layer, a tungsten nitride (WN,) layer, a nickel (Ni) layer, a cobalt (Co) layer, a chromium (Cr) layer, an antimony (Sb) layer, an iron (Fe) layer, a molybdenum (Mo) layer, a palladium (Pd) layer, a tin (Sn) layer, a zirconium (Zr) layer, a zinc (Zn) layer, and the like. These can be used alone or in a combination thereof.

The second electrode 14 may be formed by a physical vapor deposition (PVD) process or a CVD process. When the second electrode 14 includes the copper layer, the copper layer may be formed by an electroplating process or an electroless plating process.

As described above, the polyimide layer 12 may not thermally decompose at a temperature of about 500° C. Thus, the latter high-temperature processes used for manufacturing a semiconductor device may be continuously carried out without changing the temperature because of a sensitive organic material.

Further, the non-volatile organic resistance random access memory device may be operated as a non-volatile memory device without mixing nano-particles or clusters with the polyimide layer 12. As a result, contamination caused by mixing the nano-particles or the clusters with polyimide layer 12 may not be generated.

Furthermore, selections of the first and second electrodes used in the non-volatile organic resistance random access memory device need not be restricted. Thus, processes for manufacturing the non-volatile organic resistance random access memory device may be very simple and a cost for manufacturing the same may be considerably reduced.

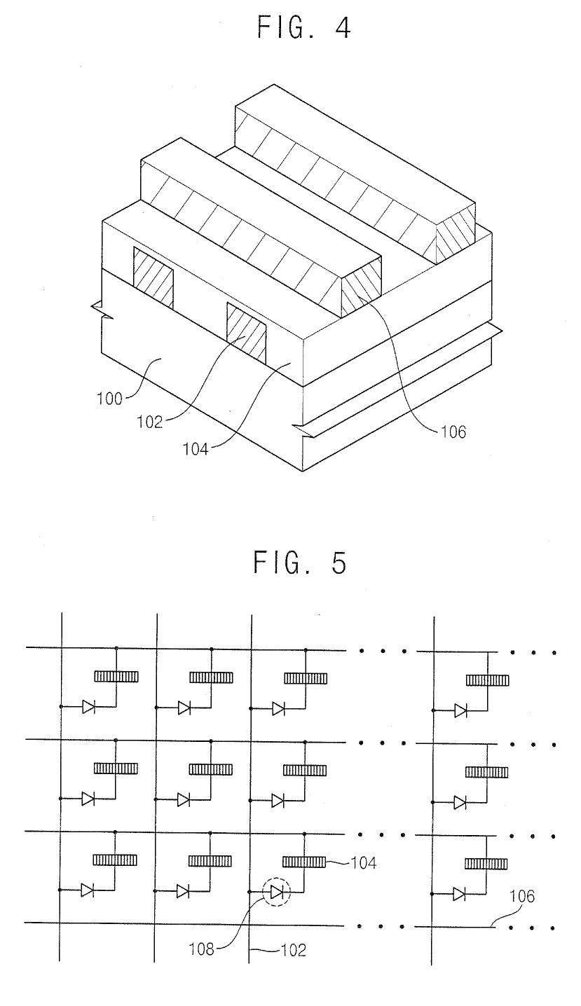

FIG. 3 is a cross-sectional view illustrating a non-volatile organic resistance random access memory device in accordance with another embodiment.

FIG. 4 is a perspective view illustrating unit cells of the non-volatile organic resistance random access memory device in FIG. 3, and FIG. 5 is a circuit diagram illustrating an array of the non-volatile organic resistance random access memory device in FIG. 3.

The non-volatile organic resistance RAM device of this example embodiment has a cross point array that includes a resistance memory cell formed at an intersection point of the first and second electrodes.

Referring to FIGS. 3 to 5, the non-volatile organic resistance random access memory (RAM) device includes a substrate 100, a first electrode 102, a second electrode 106 and a polyimide layer 104.

The substrate 100 includes a semiconductor substrate such as a silicon substrate and a silicon-on-insulation (SO) substrate, a flexible substrate including an inorganic material such as a glass or a stable organic material.

The first electrode 102 is formed on the substrate 100. The first electrode 102 may have a linear shape extending in a first direction that traverses the substrate 100. Examples of the first electrode 102 include a metal layer, a metal nitride layer, a doped semiconductor layer, and the like. These can be used alone or in a combination thereof. In this example embodiment, the metal layer or the metal nitride layer is used for the first electrode 10.

Particularly, examples of the first electrode 102 include an aluminum (Al) layer, a copper (Cu) layer, a titanium nitride (TiN) layer, a titanium aluminum nitride (TixAlyNz) layer, an iridium (Ir) layer, a platinum (Pt) layer, a silver (Ag) layer, a gold (Au) layer, a polysilicon layer, a tungsten (W) layer, a titanium (Ti) layer, a tantalum (Ta) layer, a tantalum nitride (TaN) layer, a tungsten nitride (ON) layer, a nickel (Ni) layer, a cobalt (Co) layer, a chromium (Cr) layer, an antimony (Sb) layer, an iron (Fe) layer, a molybdenum (Mo) layer, a palladium (Pd) layer, a tin (Sn) layer, a zirconium (Zr) layer, a zinc (Zn) layer, and the like. These can be used alone or in a combination thereof.

The polyimide layer 104 covers the first electrode 102. The polyimide layer 104 has a flat upper face. Thus, since the polyimide layer 104 has the flat upper face, the polyimide layer 104 has a first portion interposed between the first electrode 102 and the second electrode 106, and a second portion interposed between the substrate 100 and the second electrode 106. In this example, the second portion has a thickness greater than the first portion.

Here, only the first portion of the polyimide layer 104 on the first electrode 102 functions as the variable resistor. The first portion of the polyimide layer 104 may have a thickness of about 10 Å to about 500 Å. That is, the polyimide layer 104 between the first and second electrodes 102 and 104 has the thickness of about 10 Å to about 500 Å.

In contrast, the second portion of the polyimide layer 104 functions as an insulation interlayer. Thus, the second portion of the polyimide layer 104 may have a thickness of no less than about 500 Å. Although the thickness of the second portion of the polyimide layer 104 may vary in accordance with the thickness of the first electrode 102, the second portion of the polyimide layer 104 may have a thickness of about 500 Å to about 10,000 Å. Furthermore, the polyimide layer 104 may have has a dielectric constant lower than that of silicon oxide that is generally used for the insulation interlayer. Thus, a parasitic capacitance between the linear first electrodes 102 may be reduced.

As shown in FIG. 5, a diode 108 may be additionally arranged between the first electrode 102 and the polyimide layer 104. The diode 108 may have a linear shape that makes contact with an upper face of the first electrode 102.

The diode 108 may include two conductive plates making contact with each other where the conductive plates have different work functions. Alternatively, the diode 108 may be integrally formed with the first electrode 102 so that the first electrode 102 may function both as the diode 108 and as an electrode.

The diode 108 has a cathode coupled to the polyimide layer 104 and an anode coupled to the first electrode 102. Thus, the diode 108 prevents a current from flowing from the second electrode 106 to the first electrode 102 through the polyimide layer 104. As a result, since the diode 108 only allows the current to flow from the first electrode 102 to the second electrode 106, alteration of data in an adjacent cell due to peripheral circuits may not occur.

The second electrode 106 is formed on the flat upper face of the polyimide layer 104. The second electrode 106 may have a linear shape extending in a second direction. The second direction may be substantially perpendicular to the first direction. Examples of the second electrode 106 include a metal layer, a metal nitride layer, a doped semiconductor layer, and the like. These can be used alone or in a combination thereof. In this example embodiment, the metal layer or the metal nitride layer is used for the second electrode 106.

In particular, examples of the second electrode 106 include an aluminum (Al) layer, a copper (Cu) layer, a titanium nitride (TiN) layer, a titanium aluminum nitride (TixAlyNz) layer, an iridium (Ir) layer, a platinum (Pt) layer, a silver (Ag) layer, a gold (Au) layer, a polysilicon layer, a tungsten (W) layer, a titanium (Ti) layer, a tantalum (Ta) layer, a tantalum nitride (TaN) layer, a tungsten nitride (WN) layer, a nickel (Ni) layer, a cobalt (Co) layer, a chromium (Cr) layer, an antimony (Sb) layer, an iron (Fe) layer, a molybdenum (Mo) layer, a palladium (Pd) layer, a tin (Sn) layer, a zirconium (Zr) layer, a zinc (Zn) layer, and the like. These layers can be used alone or in a combination thereof.

The intersection point between the first electrode 102 and the second electrode 106 corresponds to the unit cell of the non-volatile organic resistance RAM device. Thus, since one unit cell is formed by the each intersection point of the first and second electrodes 102 and 106, a 4F2 cell may be embodied.

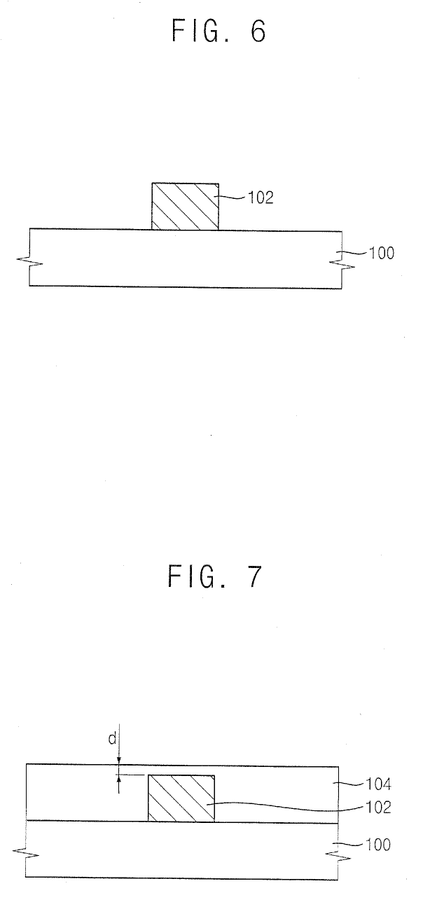

FIGS. 6 to 8 are cross-sectional views illustrating a method of manufacturing the non-volatile organic resistance random access memory device in FIG. 3.

Referring to FIG. 6, the substrate 100 on which the non-volatile organic resistance RAM device is formed is prepared. Examples of the substrate 100 include the semiconductor substrate such as a silicon substrate, a silicon-on-insulation (SOI) substrate or a flexible substrate including inorganic material such as a glass, or a stable organic material.

A conductive material is deposited on the substrate 100 to form a first electrode layer. Examples of the first electrode layer include a metal layer, a metal nitride layer, a doped semiconductor layer, and the like. These can be used alone or in a combination thereof. In this example embodiment, the metal layer or the metal nitride layer is used for the first electrode layer. In particular, examples of the first electrode layer include an aluminum (Al) layer, a copper (Cu) layer, a titanium nitride (TiN) layer, a titanium aluminum nitride (TixAlyNz) layer, an iridium (Ir) layer, a platinum (Pt) layer, a silver (Ag) layer, a gold (Au) layer, a polysilicon layer, a tungsten (W) layer, a titanium (Ti) layer, a tantalum (Ta) layer, a tantalum nitride (TaN) layer, a tungsten nitride (WN) layer, a nickel (Ni) layer, a cobalt (Co) layer, a chromium (Cr) layer, an antimony (Sb) layer, an iron (Fe) layer, a molybdenum (Mo) layer, a palladium (Pd) layer, a tin (Sn) layer, a zirconium (Zr) layer, a zinc (Zn) layer, and the like. These layers can be used alone or in a combination thereof. The first electrode layer may be formed by a process such as a physical vapor deposition (PVD) process or a CVD process.

Additionally, a diode layer (not shown) may be formed on the first electrode layer. The diode layer includes sequentially stacked conductive layers having different work functions.

A photoresist film (not shown) is then formed on the first electrode layer. The photoresist film is exposed, developed and baked to form a photoresist pattern. Here, the photoresist pattern has a linear shape extending in the first direction traversing the substrate 100. The first electrode layer is etched using the photoresist film as an etching mask to form the linear first electrode 102 extending in the first direction. The first electrode layer may be etched by a dry etching process.

When the diode layer is formed on the first electrode layer, a diode 108, electrically connected to the first electrode 102, is formed on the first electrode 102.

Here, the first electrode 102 may be formed by the photolithography process in order to simplify the entire process. However, when the first electrode layer includes a material such as the copper layer that may not be patterned by the photolithography process, the first electrode layer may be patterned by a damascene process or other process suitable for patterning the first electrode layer in order to form the first electrode 102.

Referring to FIG. 7, the polyimide layer 104 is formed on the first electrode 102 and the substrate 100. The polyimide layer 104 has a thickness for providing the polyimide layer 104 with a high resistance or a low resistance corresponding to a potential difference between the first and second electrodes 102 and 106. In this example, the first portion of the polyimide layer 104 that may be between the first and second electrodes 102 and 106 serves as the variable resistor. The second portion of the polyimide layer 104 between the substrate 100 and the second substrate 106 serves as the insulation interlayer. Thus, the first portion of the polyimide layer 104 may have a thickness of about 10 Å to about 500 Å.

In other words, the first portion of the polyimide layer 104 on the first electrode 102 has a thickness of about 10 Å to about 500 Å. The second portion of the polyimide layer 104 on the substrate 100 adjacent to the first electrode 102 has a thickness above about 500 Å.

To form the polyimide layer 104, a polyimide precursor is spin-coated on the first electrode 102 and the substrate 100. Here, an example of the polyimide precursor includes polyamic acid. The polyimide precursor is thermally treated to convert the polyimide precursor into the polyimide layer 104. That is, the polyamic acid is imidified by the thermal treatment to form the polyimide layer 104. The thermal treatment is carried out at a temperature of about 150° C. to about 450° C.

When the polyimide precursor is spin-coated, the polyimide layer 104 may have an upper face having good flatness even though an underlying layer has an irregular surface. Thus, after forming the polyimide layer 104, it is not necessary to perform an additional planarizing process.

Alternatively, the polyimide layer 104 may be formed by a chemical vapor deposition (CVD) process. However, since the polyimide layer 104 formed by the CVD process may have an irregular surface, an additional planarizing process may be used to planarize the surface of the polyimide layer 104.

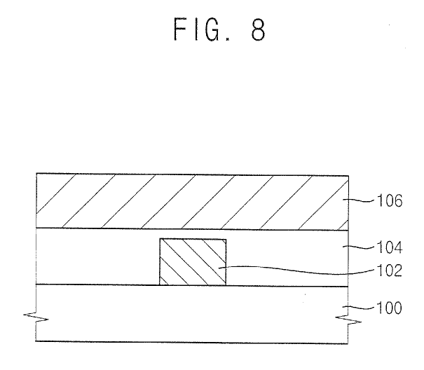

Referring to FIG. 8, metal, metal nitride or semiconductor material that is used in general semiconductor manufacturing process is deposited on the polyimide layer 104 to form a second electrode layer (not shown). Examples of the second electrode layer include an aluminum (Al) layer, a copper (Cu) layer, a titanium nitride (TiN) layer, a titanium aluminum nitride (TixAlyNz) layer, an iridium (Ir) layer, a platinum (Pt) layer, a silver (Ag) layer, a gold (Au) layer, a polysilicon layer, a tungsten (W) layer, a titanium (Ti) layer, a tantalum (Ta) layer, a tantalum nitride (TaN) layer, a tungsten nitride (WN) layer, a nickel (Ni) layer, a cobalt (Co) layer, a chromium (Cr) layer, an antimony (Sb) layer, an iron (Fe) layer, a molybdenum (Mo) layer, a palladium (Pd) layer, a tin (Sn) layer, a zirconium (Zr) layer, a zinc (Zn) layer, and the like. These can be used alone or in a combination thereof. The second electrode layer may be formed by processes such as a physical vapor deposition (PVD) process or a CVD process.

The second electrode layer is patterned to form the linear second electrode 106 extending the second direction inclined to the first direction. In this example embodiment, the second direction is substantially perpendicular to the first direction.

In particular, a photoresist film (not shown) is then formed on the second electrode layer. The photoresist film is exposed, developed and baked to form a photoresist pattern. Here, the photoresist pattern has a linear shape extending the second direction substantially perpendicular to the first direction. The second electrode layer is etched using the photoresist film as an etching mask to form the linear second electrode 102 extending in the second direction. The second electrode layer may be etched by a dry etching process using reactive plasma.

Here, the second electrode 106 may be formed by the photolithography process in order to simplify the entire process. However, when the second electrode layer includes a material such as the copper layer that may not be patterned by the photolithography process, the second electrode layer may be patterned by a damascene process or other process suitable for patterning the second electrode layer in order to form the second electrode 106.

In this example embodiment, the polyimide layer 104 used as the variable resistor has thermal and chemical stability. Thus, when subsequent semiconductor manufacturing processes such as the process for forming the second electrode layer, the photolithography process, the dry etching process, and the like are carried out after forming the polyimide layer 104, the characteristics of the polyimide layer 104 may not be deteriorated so that the polyimide layer 104 may have sufficient switching characteristics.

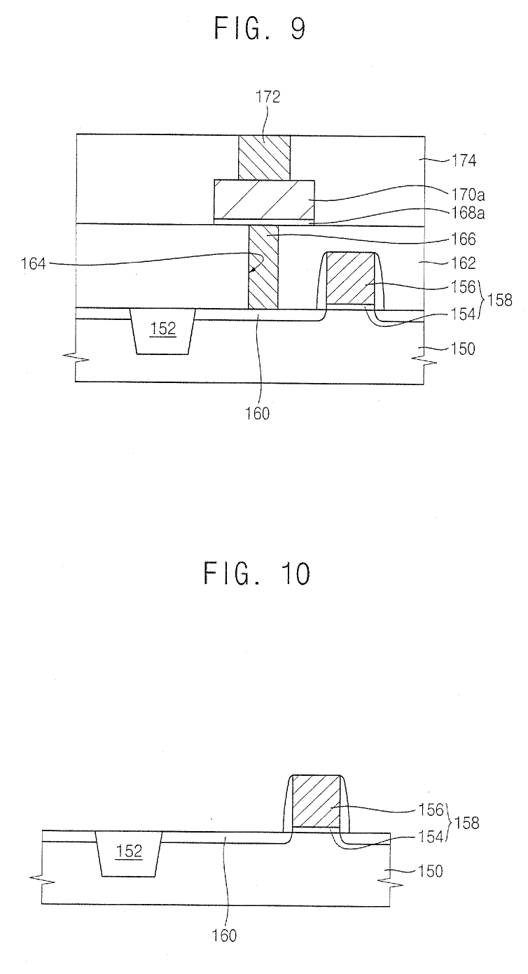

FIG. 9 is a cross-sectional view illustrating a non-volatile organic resistance random access memory device in accordance with another embodiment of the present invention.

The non-volatile organic resistance RAM device of this embodiment has a structure that includes a transistor for accessing a corresponding storage element,

Referring to FIG. 9, the non-volatile organic resistance random access memory (RAM) device of this embodiment includes a substrate 150. The substrate 100 includes a semiconductor substrate such as a silicon substrate and a silicon-on-insulator (SOT) substrate. An isolation layer 152 is formed in the substrate 150 to define an active region and a field region of the substrate 150.

A MOS transistor for accessing a corresponding address is formed on the substrate 150. The MOS transistor includes a gate structure 158 and source/drain regions 160.

An insulation interlayer 162 is formed on the substrate 150 to cover the MOS transistor. An example of the insulation interlayer 162 includes an oxide layer. Particularly, examples of the insulation interlayer 162 include a borophosphor silicate glass (BPSG) layer, a phosphor silicate glass (PSG) layer, an undoped silicate glass (USG) layer, a spin on glass (SOG) layer, and the like. The insulation interlayer 162 has an opening 164 for exposing the drain region 160 of the MOS transistor.

The opening 164 is filled with a first electrode 166 as a contact plug. Examples of the first electrode 166 include an aluminum (Al) layer, a copper (Cu) layer, a titanium nitride (TiN) layer, a titanium aluminum nitride (TixAlyNz) layer, an iridium (Ir) layer, a platinum (Pt) layer, a silver (Ag) layer, a gold (Au) layer, a polysilicon layer, a tungsten (W) layer, a titanium (Ti) layer, a tantalum (Ta) layer, a tantalum nitride (TaN) layer, a tungsten nitride (WN) layer, a nickel (Ni) layer, a cobalt (Co) layer, a chromium (Cr) layer, an antimony (Sb) layer, an iron (Fe) layer, a molybdenum (Mo) layer, a palladium (Pd) layer, a tin (Sn) layer, a zirconium (Zr) layer, a zinc (Zn) layer, and the like. These layers can be used alone or in a combination thereof.

In particular, a barrier metal layer (not shown) including the titanium layer and the titanium nitride layer is formed on an inner face of the opening 164. A metal layer (not shown) is formed on the barrier metal layer to fill up the opening 164, thereby forming the first electrode 166 that includes the barrier metal layer and the metal layer.

In this example embodiment, the contact plug in the opening 164 is used as the first electrode 166. Alternatively, a conductive layer pattern (not shown) formed on the contact plug may be used as the first electrode 166. The conductive layer pattern may include the above-mentioned layers illustrated as the examples of the first electrode 166, a doped polysilicon layer, and the like.

A polyimide layer pattern 168a is formed on the first electrode 166 and the insulation interlayer 162. The polyimide layer pattern 168a may have a thickness of about 10 Å to about 500 Å.

A second electrode 170a is formed on the polyimide layer pattern 168a. Examples of the second electrode 170a include a metal layer, a metal nitride layer, a doped semiconductor layer, and the like. These can be used alone or in a combination thereof. Particularly, examples of the second electrode 170a include an aluminum (Al) layer, a copper (Cu) layer, a titanium nitride (TiN) layer, a titanium aluminum nitride (TixAlyNz) layer, an iridium (Ir) layer, a platinum (Pt) layer, a silver (Ag) layer, a gold (Au) layer, a polysilicon layer, a tungsten (W) layer, a titanium (Ti) layer, a tantalum (Ta) layer, a tantalum nitride (TaN) layer, a tungsten nitride (WN) layer, a nickel (Ni) layer, a cobalt (Co) layer, a chromium (Cr) layer, an antimony (Sb) layer, an iron (Fe) layer, a molybdenum (Mo) layer, a palladium (Pd) layer, a tin (Sn) layer, a zirconium (Zr) layer, a zinc (Zn) layer, and the like. These can be used alone or in a combination thereof. The second electrode 170a may have an isolated pattern.

In addition, an upper electrode contact 172 may be formed on the second electrode 170a. Furthermore, the upper electrode contact 172 may be surrounded by an upper insulation interlayer 174. In addition, the upper insulation interlayer 174 may cover the second electrode 170a and the polyimide layer pattern 168a. Alternatively, the non-volatile organic resistance random access memory (RAM) device of this example embodiment includes only the upper electrode contact 172, which includes a material substantially the same as that of the second electrode 170a.

Additionally, a metal wiring (not shown) may be formed on the upper electrode contact 172. Further, a bit line (not shown) may be electrically connected to the source region of the transistor.

In this example embodiment, when a unit cell includes the access transistor, an additional diode as in Embodiment 2 is not needed, because a voltage is applied only to a selected cell.

FIGS. 10 to 14 are cross-sectional views illustrating a method of manufacturing the non-volatile organic resistance random access memory device in FIG. 9.

Referring to FIG. 10, the substrate 150 on which the non-volatile organic resistance RAM device is formed is prepared. An example of the substrate 150 includes a semiconductor substrate such as a silicon substrate and a silicon-on-insulation (SOI) substrate. A trench isolation layer 152 is formed in the substrate 150 to define the active region and the field region.

Particularly, a pad oxide layer (not shown) and a pad nitride layer (not shown) are sequentially formed on the semiconductor substrate 150. The pad oxide layer and the pad nitride layer are patterned to form a pad oxide layer pattern and a pad nitride layer pattern partially exposing a surface of the semiconductor substrate 150. The semiconductor substrate 150 is etched using the pad oxide layer pattern and the pad nitride layer pattern as etching masks to form a trench at a surface portion of the semiconductor substrate 150. The semiconductor substrate 150 is thermally treated to cure damages of the semiconductor substrate 150 generated by the formation of the trench. An oxide layer (not shown) having good gap-filling characteristic is formed on the semiconductor substrate 150 to fill up the trench. Here, the oxide layer may be formed by a plasma-enhanced chemical vapor deposition (PECVD) process. The oxide layer is removed by a chemical mechanical polishing (CMP) process to expose a surface of the pad nitride layer pattern. The pad nitride layer pattern and the pad oxide layer pattern are then removed by an etching process using a phosphorous acid solution. As a result, the oxide layer exists only in the trench to complete the trench isolation layer 152.

A gate oxide layer (not shown) and a gate conductive layer (not shown) are sequentially formed on the substrate 150. The gate oxide layer and the gate conductive layer are patterned to form the gate structure 158 sequentially formed by a stacked gate oxide layer pattern 154 and gate conductive layer pattern 156.

Impurities are implanted into the substrate 150 at both sides of the gate structure 158 by an ion implantation process to form the source/drain regions 160, thereby completing the access transistor.

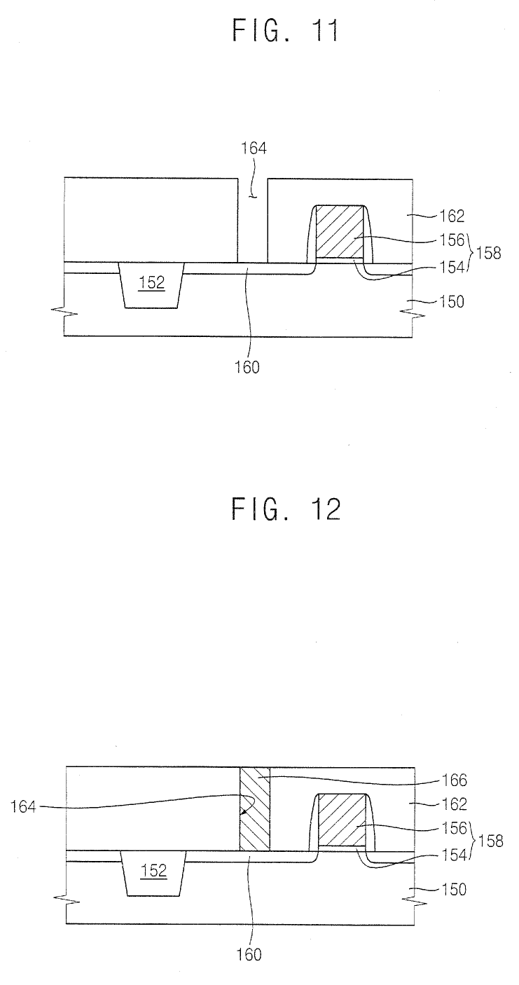

Referring to FIG. 11, the insulation interlayer 162 is formed on the substrate 150 by a CVD process. An example of the insulation interlayer 162 includes an oxide layer. Particularly, examples of the insulation interlayer 162 include a borophosphor silicate glass (BPSG) layer, a phosphor silicate glass (PSG) layer, an undoped silicate glass (USG) layer, a spin on glass (SOG) layer, and the like.

After forming the insulation interlayer 162 on the substrate 150, the insulation interlayer 162 is partially etched by a photolithography process to form the opening 164 exposing the drain region 160 of the MOS transistor.

In particular, a photoresist pattern (not shown) is formed on the insulation interlayer 162. Here, the photoresist pattern exposes a portion of the insulation interlayer 162 over the drain region 160. The insulation interlayer 162 is etched using the photoresist pattern as an etching mask to form the opening 164 exposing the drain region 160.

Referring to FIG. 12, a conductive layer is formed on the insulation interlayer 162 to fill up the opening 164. Examples of the conductive layer include an aluminum (Al) layer, a copper (Cu) layer, a titanium nitride (TiN) layer, a titanium aluminum nitride (TixAlyNz) layer, an iridium (Ir) layer, a platinum (Pt) layer, a silver (Ag) layer, a gold (Au) layer, a polysilicon layer, a tungsten (W) layer, a titanium (Ti) layer, a tantalum (Ta) layer, a tantalum nitride (TaN) layer, a tungsten nitride (WN) layer, a nickel (Ni) layer, a cobalt (Co) layer, a chromium (Cr) layer, an antimony (Sb) layer, an iron (Fe) layer, a molybdenum (Mo) layer, a palladium (Pd) layer, a tin (Sn) layer, a zirconium (Zr) layer, a zinc (Zn) layer, and the like. These layers can be used alone or in a combination thereof.

In particular, the barrier metal layer (not shown) including the titanium layer and the titanium nitride layer is formed on the inner face of the opening 164. The metal layer (not shown) is formed on the barrier metal layer to fill up the opening 164, thereby forming the conductive layer that includes the barrier metal layer and the metal layer. Furthermore, the conductive layer may be formed by processes such as a CVD process, a PVD process, and the like.

The conductive layer is partially removed by a planarizing process such as a CMP process until a surface of the insulation interlayer 162 is exposed to form the first electrode 166 in the opening 164.

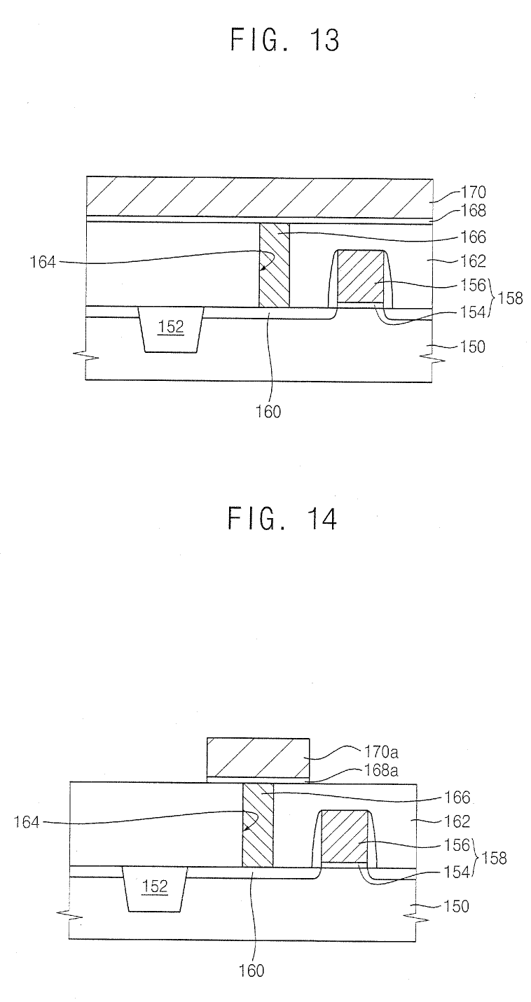

Referring to FIG. 13, a polyimide layer 168 is formed on the first electrode 166 and the insulation interlayer 162. The polyimide layer 168 may have a thickness of about 10 Å to about 500 Å.

To form the polyimide layer 168, a polyimide precursor is spin-coated on the first electrode 166. The polyimide precursor is thermally treated to convert the polyimide precursor into the polyimide layer 168. Here, the polyimide precursor includes polyamic acid. Further, the thermal treatment may be carried out at a temperature of about 150° C. to about 450° C.

A conductive material that is used in general semiconductor manufacturing process is deposited on the polyimide layer 168 to form a second electrode layer 170. Examples of the second electrode layer 170 include an aluminum (Al) layer, a copper (Cu) layer, a titanium nitride (TiN) layer, a titanium aluminum nitride (TixAlyNz) layer, an iridium (Ir) layer, a platinum (Pt) layer, a silver (Ag) layer, a gold (Au) layer, a polysilicon layer, a tungsten (W) layer, a titanium (Ti) layer, a tantalum (Ta) layer, a tantalum nitride (TaN) layer, a tungsten nitride (WN) layer, a nickel (Ni) layer, a cobalt (Co) layer, a chromium (Cr) layer, an antimony (Sb) layer, an iron (Fe) layer, a molybdenum (Mo) layer, a palladium (Pd) layer, a tin (Sn) layer, a zirconium (Zr) layer, a zinc (Zn) layer, and the like. These layers can be used alone or in a combination thereof. The second electrode layer may be formed by a process such as a physical vapor deposition (PVD) process or a CVD process.

Referring to FIG. 14, the second electrode layer 170 and the polyimide layer 168 are patterned to form the second electrode 170a and the polyimide layer pattern 168a. Although it is not necessary to etch the polyimide layer 168, since the polyimide layer 168 has the thin thickness of about 10 Å to about 500 Å, it may be very difficult to etch only the second electrode layer 170 without generations of residues or stringer failures. Thus, the polyimide layer 168 may be patterned simultaneously with the second electrode layer 170.

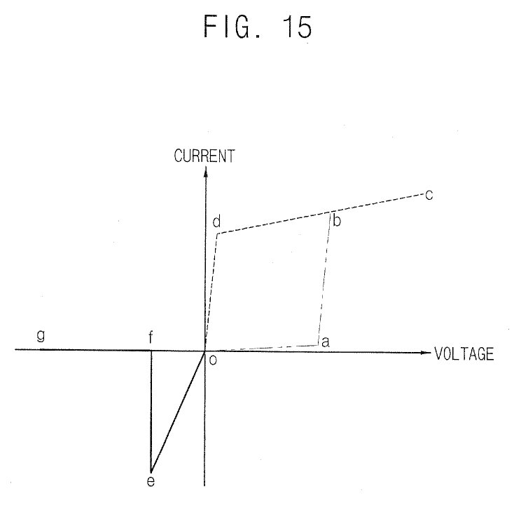

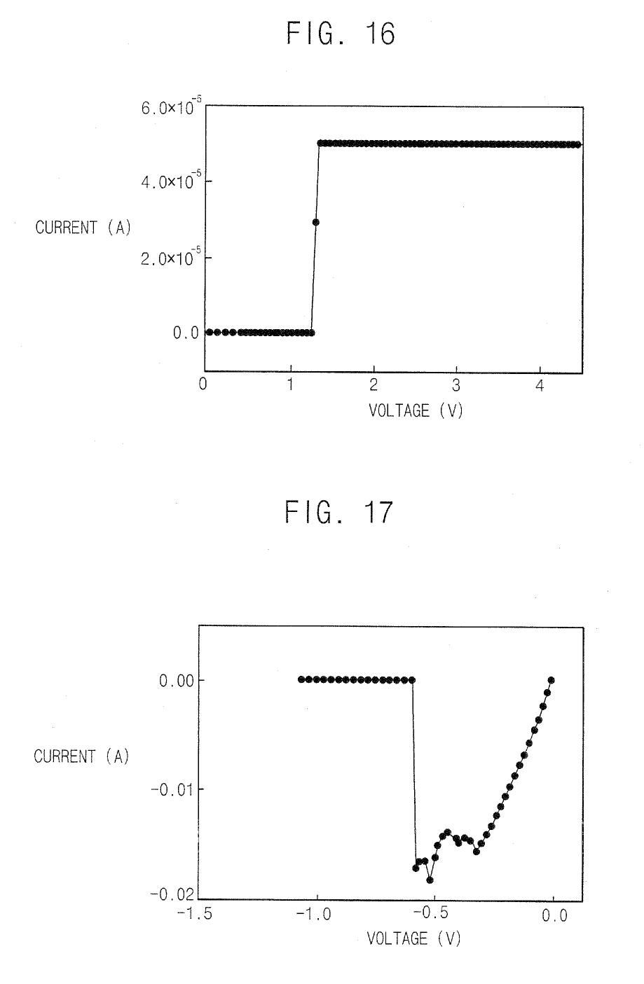

Referring to FIG. 9, the upper insulation interlayer 174 covers the polyimide layer pattern 168a, the second electrode 170a. A contact hole is formed through the upper insulation interlayer 174 to expose the second electrode 170a. The contact hole is filled with a conductive material to form the upper electrode contact. Alternatively, the process for forming the upper electrode contact may be omitted. A bit line may be further electrically connected to the upper electrode contact. Switching Characteristics of a Non-Volatile Organic Resistance RAM Device FIG. 15 is a graph illustrating switching characteristics of the non-volatile organic resistance random access memory device of the present invention. Referring to FIG. 15, an initial resistance of the non-volatile organic resistance RAM device is a high resistance state.

When a first voltage V applied to the first and second electrodes is increased to a point a on the graph, a current I hardly flows because the high resistance state is maintained to the point a. When the first voltage is substantially equal to that of the point a, the non-volatile organic resistance RAM device is switched so that a high resistance state is converted into a low resistance state allowing for the current I higher by several orders of magnitude than that in the high resistance state, to flow through the non-volatile organic resistance RAM device.

Here, the switching of the non-volatile organic resistance RAM device is referred to as a setting of the non-volatile organic resistance RAM device. Furthermore, the low resistance state is referred to as a set state. Although the voltage is increased from a point b to a point c on the graph, the set state is still maintained.

A second voltage having a polarity opposite to that of the first voltage is applied to the first and second electrodes to convert the low resistance state into the high resistance state. That is, when a negative bias is applied to the first and second electrodes, the non-volatile organic resistance RAM device is switched so that the resistance of the non-volatile organic resistance RAM device, which is operated under the low resistance state till a point e on the graph, is radically increased to a point f on the graph. Here, this switching is referred to as a resetting and the high resistance state is referred to as a reset state. When the negative bias is continuously applied to the first and second electrodes, the reset state is maintained from the point f to a point g on the graph. Further, when a positive bias is applied to the first and second electrodes, the non-volatile organic resistance RAM device is maintained as the high resistance state so that a path o-a-b-c is repeated.

Thus, when the set state is defined as data ‘0’ and the reset state is defined as data ‘1’, a voltage in the point a, that is, a set voltage Vset is applied to the first and second electrode to write the data ‘0’ into the non-volatile organic resistance RAM device. On the contrary, a voltage in the point f, that is, a reset voltage Vreset is applied to the first and second electrodes to write the data ‘1’ into non-volatile organic resistance RAM device. Further, a specific voltage selected within the 0V to the set voltage Vset is applied to the non-volatile organic resistance RAM device. A current measured from the non-volatile organic resistance RAM device is compared with a reference current to read the data ‘0’ or ‘1’ from the non-volatile organic resistance RAM device.

Furthermore, although the power supplied to the non-volatile organic resistance RAM device is cut off, the data ‘0’ or ‘1’ in the non-volatile organic resistance RAM device is still maintained.

First Evaluating Setting and Resetting Characteristics of the Non-Volatile Organic Resistance RAM Device

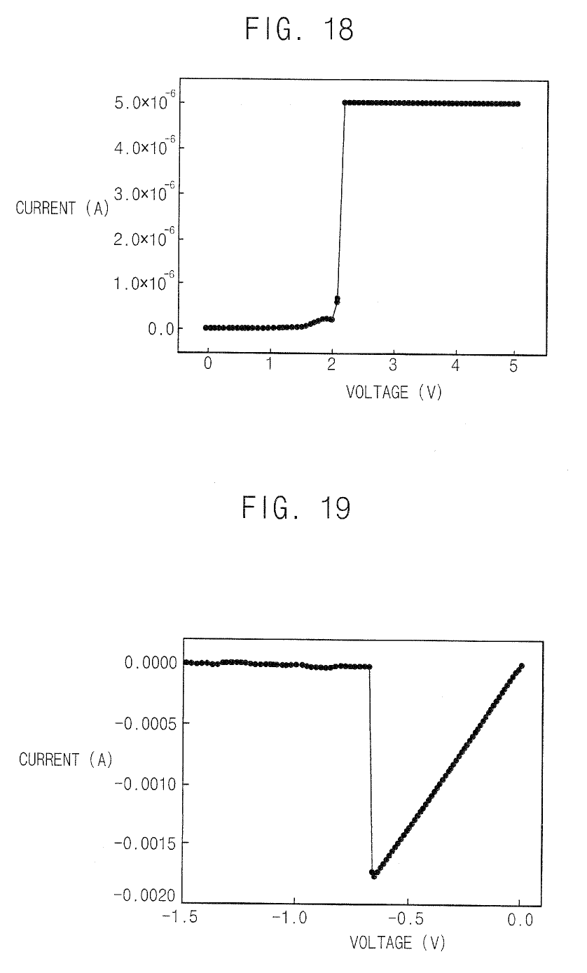

FIG. 16 is a graph illustrating setting characteristics of a first sample corresponding to the non-volatile organic resistance random access memory device in accordance with the second example embodiment, and FIG. 17 is a graph illustrating resetting characteristics of the first sample.

The first sample used in the first evaluation included a semiconductor substrate. A first electrode was formed on the semiconductor substrate. The first electrode included an aluminum layer formed by a PVD process. Further, the first electrode had a thickness of 1,500 Å. The first electrode had a linear shape that included a width of 100 μm and extended in a first direction. Here, the first electrode was formed using a metal shadow mask including an opening that had a width of 100 μm.

A polyamic acid layer was spin-coated on the first electrode. The polyamic acid layer was cured under a nitrogen atmosphere maintaining a temperature of 200° C. for about 45 minutes to form a polyimide layer having a thickness of 200 Å to about 300 Å. A second electrode including an aluminum layer was formed on the polyimide layer by PVD process. The second electrode had a thickness of 1,500 Å. Further, the second electrode had a linear shape that had a width of 100 μm and extended in a second direction substantially perpendicular to the first direction. The second electrode was formed by patterning a conductive layer.

An intersection point between the first and second electrodes functioned as the non-volatile organic resistance RAM device.

Referring to FIG. 16, a current passing through the first sample was measured with a voltage being increased in a positive direction. The first sample was switched at a point when about 1.2V was applied.

Here, when an excessive current flowed through the first sample due to maintenance of a low resistance state under a voltage higher than a set voltage Vset, the first sample might be damaged. Thus, in this evaluation, a current limit was applied to the first sample to restrict the current flow.

Referring to FIG. 17, a current passing through the first sample was measured with a voltage being increased in a negative direction. The first sample was switched at a point when about −0.5V was applied.

As shown in FIGS. 16 and 17, it could be noted that the non-volatile organic resistance RAM device, which included the polyimide layer as a variable resistor and the aluminum electrodes positioned at both sides of the polyimide layer had sufficient switching characteristics.

Second Evaluating Setting and Resetting Characteristics of the Non-Volatile Organic Resistance RAM Device

FIG. 18 is a graph illustrating setting characteristics of a second sample corresponding to the non-volatile organic resistance random access memory device in accordance with the second example embodiment, and FIG. 19 is a graph illustrating resetting characteristics of the second sample.

The second sample included first and second electrodes having a line width narrower than that of the first and second electrodes in the first sample. Further, the first and second electrodes of the second sample included different materials.

The second sample used in the second evaluation included a semiconductor substrate. A first electrode was formed on the semiconductor substrate. The first electrode included an iridium layer formed by a PVD process. Furthermore, the first electrode had a thickness of 600 Å. The first electrode had a linear shape that included a width of 0.31 μm and extended in a first direction. Here, the first electrode was formed by patterning a conductive layer.

A polyamic acid layer was spin-coated on the first electrode. The polyamic acid layer was cured under a nitrogen atmosphere maintaining a temperature of 200° C. for about 45 minutes to form a polyimide layer having a thickness of 200 Å to about 0300 Å.

A second electrode including an aluminum layer was formed on the polyimide layer by PVD process. The second electrode had a thickness of 1,500 Å. Further, the second electrode had a linear shape that had a width of 0.3 m and extended in a second direction substantially perpendicular to the first direction. The second electrode was formed by patterning a conductive layer.

An intersection point between the first and second electrodes functioned as the non-volatile organic resistance RAM device.

Referring to FIG. 18, a current passing through the second sample was measured by a voltage being increased in a positive direction. The second sample was switched at a point when about 2.0V was applied.

Here, when an excessive current flowed through the second sample due to maintenance of a low resistance state under a voltage higher than a set voltage Vset, the second sample might be damaged. Thus, in this evaluation, a current limit was applied to the second sample to restrict the current flow.

Referring to FIG. 19, a current passing through the second sample was measured by a voltage being increased in a negative direction. The second sample was switched at a point when about −0.7V was applied.

As shown in FIGS. 18 and 19, although the first and second electrodes had the line width of 0.3 μm, it could be noted that the non-volatile organic resistance RAM device had sufficient switching characteristics.

As a result, as shown in the first and second evaluations with respect to the setting and resetting characteristics of the non-volatile organic resistance RAM device, although the kinds of the electrodes are changed, it can be noted that the polyimide layer sufficiently functions as the variable resistor. Therefore, when the polyimide layer is used as the variable resistor, the non-volatile organic resistance RAM device having sufficient intrinsic functions may be manufactured without using peculiar electrodes.

Testing the First Sample that is Repeatedly Set and Reset

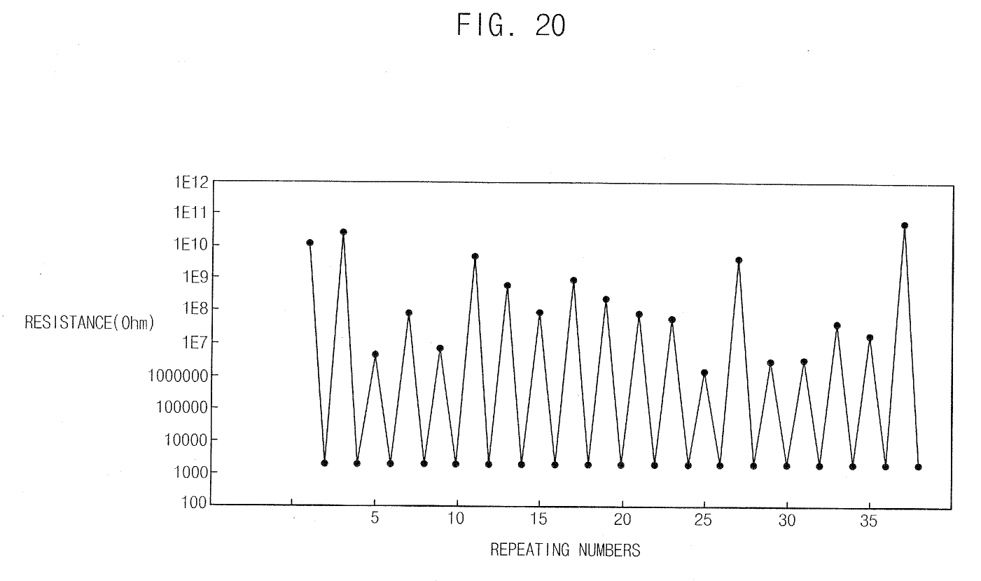

FIG. 20 is a graph illustrating resistance variances of the first sample that is repeatedly set and reset.

Referring to FIG. 20, resistances of the first sample that was repeatedly set and reset 35 times were measured. A difference between resistances of set state and reset state was no less than 3 orders of magnitude. Thus, it could be noted that the first sample had a sufficient sensing margin required in a memory device.

According to an embodiment, since the non-volatile organic resistance RAM device has excellent thermal and chemical stability, the non-volatile organic resistance RAM device may have improved reliability and durability.

Furthermore, the non-volatile organic resistance RAM device has good switching characteristics so that the non-volatile organic resistance RAM device may have improved operational characteristics.

Furthermore, the non-volatile organic resistance RAM device may be formed by simple processes.

Although embodiments have been described in detail, modifications and variations can be made by persons skilled in the art in light of the above teachings without departing from the scope and the spirit of the following claims.

What is claimed is:

1. A non-volatile organic resistance memory device, comprising:
a first electrode;
a second electrode; and
a polyimide layer interposed between the first and second electrodes, the polyimide layer having a thickness such that a resistance of the polyimide layer varies in accordance with a potential difference between the first and second electrodes.

2. The device of claim 1, wherein each of the first and second electrodes comprises at least one of a metal, a metal nitride material, and a doped semiconductor material.

3. The device of claim 1, wherein each of the First and second electrodes comprises at least one selected from the group consisting of an aluminum (Al) layer, a copper (Cu) layer, a titanium nitride (TiN) layer, a titanium aluminum nitride (TixAlyNz) layer, an iridium (Ir) layer, a platinum (Pt) layer, a silver (Ag) layer, a gold (Au) layer, a polysilicon layer, a tungsten (W) layer, a titanium (Ti) layer, a tantalum (Ta) layer, a tantalum nitride (TaN) layer, a tungsten nitride (WN) layer, a nickel (Ni) layer, a cobalt (Co) layer, a chromium (Cr) layer, an antimony (Sb) layer, an iron (Fe) layer, a molybdenum (Mo) layer, a palladium (Pd) layer, a tin (Sn) layer, a zirconium (Zr) layer, and a zinc (Zn) layer.

4. The device of claim 1, wherein the polyimide layer has a thickness of about 10 Å to about 500 Å.

5. The device of claim 1, further comprising:
a substrate; and
an insulation interlayer disposed on the substrate;
wherein the first electrode is formed in the insulation interlayer and is electrically coupled to an impurity region in the substrate.

6. The device of claim 5, further comprising:
an access transistor formed on the substrate;
wherein the impurity region comprises a drain region of the access transistor.

7. The device of claim 1, further comprising:
a substrate;
wherein:
the first electrode is disposed on the substrate;
the polyimide layer is disposed on a plurality of sidewalls of the first electrode and a top surface of the first electrode; and
the second electrode is disposed on the polyimide layer over the first electrode.

8. The device of claim 7, wherein the polyimide layer includes self-generated nano-particles.

9. The device of claim 8, wherein the self-generated nano-particles are nano-particles generated by a reaction between the polyimide layer and at least one of the first electrode and the second electrode.

10. The device of claim 8, wherein nano-particles within the polyimide layer include only the self-generated nano-particles.

11. The device of claim 8, wherein the self-generated nano-particles include particles from at least one of the first electrode and the second electrode.

12. The device of claim 7, wherein the polyimide layer is continuous between a first sidewall of the first electrode and a second sidewall of the first electrode.

13. The device of claim 1, further comprising:
a source/drain region;
an insulating layer disposed over the source/drain region; and
an opening in the insulating layer exposing the source/drain region;
wherein:
the first electrode is disposed in the opening;
the polyimide layer disposed on the first electrode; and
the second electrode is disposed on the polyimide layer.

14. The device of claim 13, wherein the second electrode substantially overlaps the entire polyimide layer.

15. The device of claim 13, wherein the polyimide layer is disposed on the insulating layer.

16. A method of manufacturing a non-volatile organic resistance memory device, comprising:
forming a first electrode on a substrate;
forming a polyimide layer on the first electrode; and
forming a second electrode on the polyimide layer;
wherein the polyimide layer has a thickness such that a resistance of the polyimide layer varies in accordance with a potential difference between the first and second electrodes.

17. The method of claim 16, wherein forming the second electrode further comprises forming the second electrode before any doping of the polyimide layer.

18. The method of claim 16, wherein each of forming the first electrode and forming the second electrodes further comprises:
depositing at least one selected from the group consisting of a metal, a metal nitride material, and a doped semiconductor material.

19. The method of claim 16, wherein forming the polyimide layer further comprises:
forming the polyimide layer such that self-generated nano-particles are generated in the polyimide layer.

20. The method of claim 16, wherein each of forming the first electrode and forming the second electrode further comprises:
forming at least one selected from the group consisting of an aluminum (Al) layer, a copper (Cu) layer, a titanium nitride (TiN) layer, a titanium aluminum nitride (TixAlyNz) layer, an iridium (Ir) layer, a platinum (Pt) layer, a silver (Ag) layer, a gold (Au) layer, a polysilicon layer, a tungsten (W) layer, a titanium (Ti) layer, a tantalum (Ta) layer, a tantalum nitride (TaN) layer, a tungsten nitride (WN) layer, a nickel (Ni) layer, a cobalt (Co) layer, a chromium (Cr) layer, an antimony (Sb) layer, an iron (Fe) layer, a molybdenum (Mo) layer, a palladium (Pd) layer, a tin (Sn) layer, a zirconium (Zr) layer and a zinc (Zn) layer.

21. The method of claim 16, wherein forming the first electrode comprises:
doping the substrate with impurities to form impurity regions;
forming an insulation interlayer on the substrate, the insulation interlayer having an opening that exposes the impurity regions; and
filling the opening with a conductive material to form the first electrode.

22. The method of claim 16, wherein forming the polyimide layer comprises:
spin-coating a polyimide precursor on the first electrode; and
thermally treating the polyimide precursor to convert the polyimide precursor into the polyimide layer.

23. The method of claim 22, wherein spin-coating the polyimide precursor further comprises spin-coating polyamic acid.

24. The method of claim 22, further comprising thermally treating the polyimide precursor at a temperature of about 150° C. to about 450° C.

25. The method of claim 16, wherein forming the polyimide layer further comprises forming the polyimide layer having a thickness of about 10 Å to about 500 Å.

26. The method of claim 16, wherein forming the first electrode comprises:
forming a conductive layer on the substrate; and
patterning the conductive layer to form the first electrode having a linear shape that extends in a first direction traversing the substrate;
wherein forming the second electrode comprises:
forming a conductive layer on the polyimide layer; and
patterning the conductive layer to form the second electrode having a linear shape that extends in a second direction inclined to the first direction.

27. The method of claim 26, further comprising forming a diode electrically connected to any one of the first and second electrodes.

28. The method of claim 16, further comprising forming a MOS transistor for accessing the non-volatile organic resistance memory device on the substrate, wherein the first electrode is electrically connected to a drain region of the MOS transistor.

29. A non-volatile organic resistance memory device, comprising:
a first electrode formed on a substrate, the first electrode extending in a first direction;
a polyimide layer covering the first electrode: and
a second electrode formed on the polyimide layer, the second electrode extending in a second direction inclined to the first direction.

30. The device of claim 29, wherein each of the first electrode and the second electrode has a substantially linear shape.

31. The device of claim 29, wherein the polyimide layer has a substantially flat upper face.

32. The device of claim 29, wherein each of the first and second electrodes comprises at least one of a metal, a metal nitride material, and a doped semiconductor material.

33. The device of claim 29, wherein a portion of the polyimide layer on the first electrode has a thickness of about 10 Å to about 500 Å.

34. The device of claim 29, further comprising a diode electrically coupled to any one of the first and second electrodes.

35. A method of manufacturing a non-volatile organic resistance memory device, comprising:
forming a first electrode on a substrate, the first electrode extending in a first direction;
forming a polyimide layer on the first electrode; and
forming a second electrode on the polyimide layer, the second electrode extending in a second direction inclined to the first direction.

36. The method of claim 35, wherein:
forming the first electrode on the substrate further comprises forming the first electrode having a substantially linear shape; and
forming the second electrode on the polyimide layer further comprises forming the second electrode having a substantially linear shape.

37. The method of claim 35, wherein:
forming the polyimide layer on the first electrode further comprises forming the polyimide layer having a substantially flat upper face.

38. The method of claim 35, wherein forming the polyimide layer comprises:
spin-coating a polyimide precursor on the first electrode; and
thermally treating the polyimide precursor to convert the polyimide precursor into the polyimide layer.

39. The method of claim 35, wherein a portion of the polyimide layer on the first electrode has a thickness of about 10 Å to about 500 Å.

40. The method of claim 35, further comprising forming a diode electrically coupled to any one of the first and second electrodes.
